(19) United States
(12) Patent Application Publication
(10) Pub. No.: US 2025/0194047 A1
(43) Pub. Date: Jun. 12, 2025

(54) COOLING INTEGRATED SYSTEM

(71) Applicant: BITMAIN TECHNOLOGIES INC., Beijing (CN)

(72) Inventors: Shaoming HUANG, Beijing (CN); Hangkong HU, Beijing (CN); Hongbo ZENG, Beijing (CN); Mingliang HAO, Beijing (CN); Shengqiang XIAO, Beijing (CN); Pengfei ZHENG, Beijing (CN); Yurong PENG, Beijing (CN); Te PI, Beijing (CN); Fengjie LI, Beijing (CN); Hongshan ZHU, Beijing (CN)

(21) Appl. No.: 19/054,456

(22) Filed: Feb. 14, 2025

Related U.S. Application Data
(63) Continuation of application No. PCT/CN2023/109647, filed on Jul. 27, 2023.

(30) Foreign Application Priority Data
Aug. 16, 2022 (CN) 202222157258.5

(51) Int. Cl. H05K 7/20

(52) U.S. Cl. CPC H05K 7/20272; H05K 7/20263; H05K 7/20781; H05K 7/20136

(57) ABSTRACT

It relates to the technical field of cooling devices, a cooling integrated system configured to cool a computing device provided with a cooling channel, which includes a housing and a cooling apparatus integrally packaged inside the housing. The cooling apparatus includes a heat exchange mechanism, a liquid inlet pipe, a liquid return pipe, and a delivery pump. The heat exchange mechanism and the cooling channel are communicated by the liquid inlet pipe, and the heat exchange mechanism and the cooling channel are communicated by the liquid return pipe. The delivery pump is installed on the liquid inlet pipe and/or the liquid return pipe and configured to circulate coolant between the heat exchange mechanism and the cooling channel to cool the computing device. The cooling apparatuses in the cooling integrated system of the embodiments of the present application are integrally configured.

### CROSS-REFERENCE TO RELATED APPLICATION

This application is a continuation of International Application No. PCT/CN2023/109647, filed on Jul. 27, 2023, which claims priority to Chinese Patent Application No. 202222157258.5, filed on Aug. 16, 2022, both of which are hereby incorporated by reference in their entireties.

### TECHNICAL FIELD

The present application relates to the technical field of cooling devices, and in particular, to a cooling integrated system.

### BACKGROUND

A server is a high-performance computer in a network environment that listens to service requests submitted by other computers (clients) on the network and provides corresponding services. The server must have the ability to undertake services and guarantee services, so that higher requirements are need to be satisfied in terms of stability, security, performance, etc. Therefore, power supplies of servers usually adopt enhanced heat dissipation designs to improve working stability and service life, so as to fully satisfy the requirements of the servers for being able to work continuously for 24 hours a day.

Most servers use traditional air-cooling or liquid-cooling approaches for

heat dissipation. For air-cooling, fans are utilized to enhance air flow to facilitate the heat dissipation of the server into the air; for liquid-cooling, working fluid is utilized as an intermediate heat transmission medium, to transfer heat from a hot area to a distant location for further cooling. Since the specific heat capacity of liquid is much greater than that of air and the heat dissipation speed of liquid is much greater than that of air, the cooling efficiency of liquid-cooling is much higher than that of air-cooling.

However, during the implementation of the present application, the inventors of the present application found that internal components of the cooling apparatus of the currently used cooling integrated system that adopts liquid-cooling to cool servers are all separately configured when manufacturing, and users need to connect the internal components of the cooling apparatus personally during usage.

### SUMMARY

The main technical problem to be solved by embodiments of the present application is to provide a cooling integrated system, cooling apparatuses in which are integrally configured, so that users do not need to connect the cooling apparatus and a cooling channel of the server personally.

In order to solve the above technical problems, a technical solution adopted by the present application is to provide a cooling integrated system for cooling a computing device provided with a cooling channel. The cooling integrated system includes a housing and a cooling apparatus integrally packaged inside the housing. The cooling apparatus includes a heat exchange mechanism, a liquid inlet pipe, a liquid return pipe, and a delivery pump. The heat exchange mechanism and the cooling channel are communicated by the liquid inlet pipe, and the heat exchange mechanism and the cooling channel are communicated by the liquid return pipe. The delivery pump is installed on the liquid inlet pipe and/or the liquid return pipe and configured to circulate coolant between the heat exchange mechanism and the cooling channel to cool the computing device.

In an embodiment, the housing includes a container, and the cooling apparatus is accommodated inside the container.

In an embodiment, an interior of the container is divided along a length direction to form a first cavity and a second cavity, the liquid inlet pipe and the liquid return pipe are provided in the first cavity, and the heat exchange mechanism is provided in the second cavity, and the delivery pump is provided in the first cavity and/or the second cavity.

In an embodiment, the cooling integrated system further includes a rack, and the rack is accommodated in the first cavity, the rack includes multiple layers of stacked placement space, and the placement space is configured to accommodate the computing device provided with the cooling channel.

In an embodiment, the cooling integrated system further includes a power distribution cabinet, and the power distribution cabinet is provided on a side of the rack facing away from the heat exchange mechanism in the length direction.

In an embodiment, the cooling integrated system further includes a control apparatus, and the control apparatus is provided above the power distribution cabinet.

In an embodiment, the container is provided with an air inlet and an air outlet; the cooling integrated system further includes a fan, and the fan is installed on the container and arranged to directly face the air outlet and/or the air inlet.

In an embodiment, the number of the fan is three, and the three fans are arranged in a row along the length direction.

In an embodiment, the cooling integrated system further includes a protective fence, and the protective fence is installed on the container and arranged around the fan.

In an embodiment, the fan and the protective fence are detachably installed on the container.

The beneficial effects of the embodiments of the present application lie in that: different from the prior art, the cooling apparatuses in the cooling integrated system of the embodiments of the present application are integrally configured, so that the users do not need to connect the cooling apparatus and the cooling channel of the server personally.

### BRIEF DESCRIPTION OF DRAWINGS

In order to more clearly illustrate the technical solutions of embodiments of the present application, drawings needed to be used for the description of the embodiments will be briefly introduced below. Obviously, the drawings in the following description are some embodiments of the present application. For those skilled in the art, other drawings similar to these drawings can be obtained without exerting creative efforts.

FIG. 1 is a perspective schematic diagram of a cooling integrated system according to an embodiment of the present application.

FIG. 2 is a schematic cross-sectional view of the cooling integrated system in FIG. 1 along a line A-A.

FIG. 3 is a schematic view of the cooling integrated system from an angle according to an embodiment of the present application.

FIG. 4 is a perspective schematic diagram of a rack according to an embodiment of the present application.

FIG. 5 is a partially enlarged schematic view at B in FIG. 4.

In the figures, 1: Cooling integrated system; 2: Server; 100: Housing; 110: First container; 111: First cavity; 122: Air inlet; 120: Second container; 121: Second cavity; 123: Air outlet; 200: Rack; 201: Placement space; 210: Upright column; 211: First mounting hole; 212: Fixing part; 220: Carrying beam; 221: Second mounting hole; 230: Partition; 240: Fixing plate; 300: Cooling apparatus; 310: Heat exchange mechanism; 311: Heat dissipation pipe; 320: Liquid inlet pipe; 330: Liquid return pipe; 340: Delivery pump; 400: Fan; 500: Protective fence; 600: Ladder; 700: Ladder protection cage; 800: Power distribution cabinet; 900: Control apparatus; X: Length direction; Y: Width direction; Z: Height direction.

### DESCRIPTION OF EMBODIMENTS

The technical solutions in embodiments of the present application will be described clearly and comprehensively below with reference to the accompanying drawings in the embodiments of the present application. Obviously, the described embodiments are part of the embodiments of the present application, not all of the embodiments. Based on the embodiments in the present application, all other embodiments obtained by those skilled in the art without creative effort fall within the protection scope of the present application.

It should also be understood that the terms used in the specification of the present application are for the purpose of describing particular embodiments only and are not intended to limit the present application. As used in the specification of the present application and the appended claims, the singular forms “a”, “an” and “the” are intended to include the plural form unless the context clearly dictates otherwise.

It should further be understood that the term “and/or” as used in the specification of the present application and the appended claims refers to any and all possible combinations of one or more of the associated listed items, and includes such combinations.

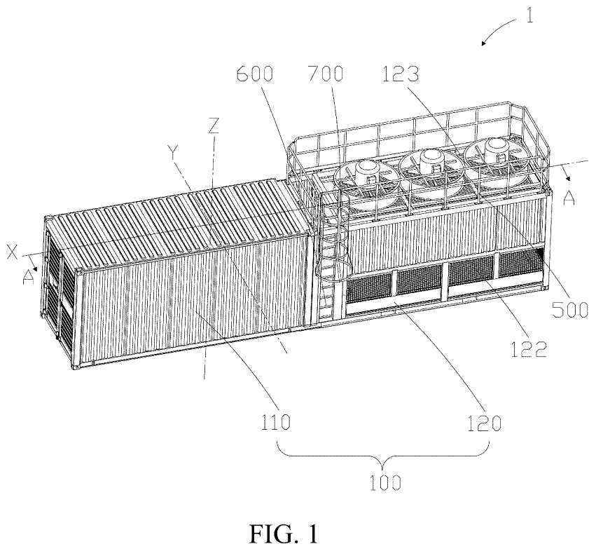

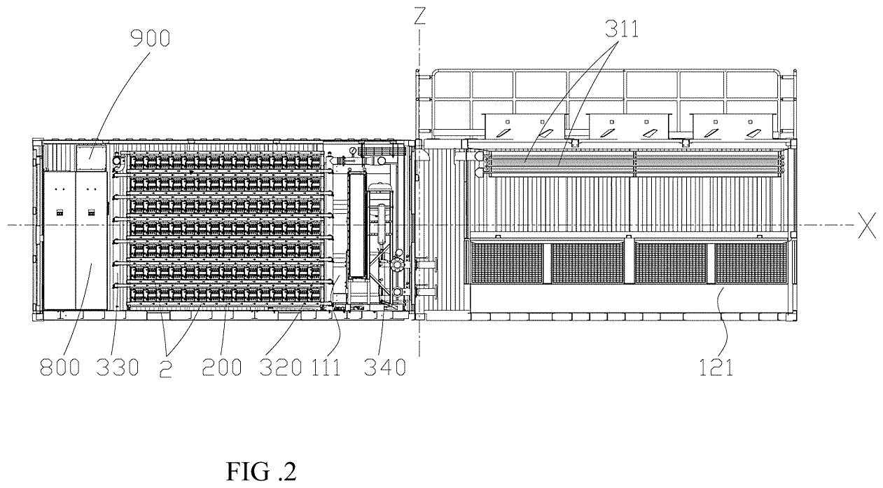

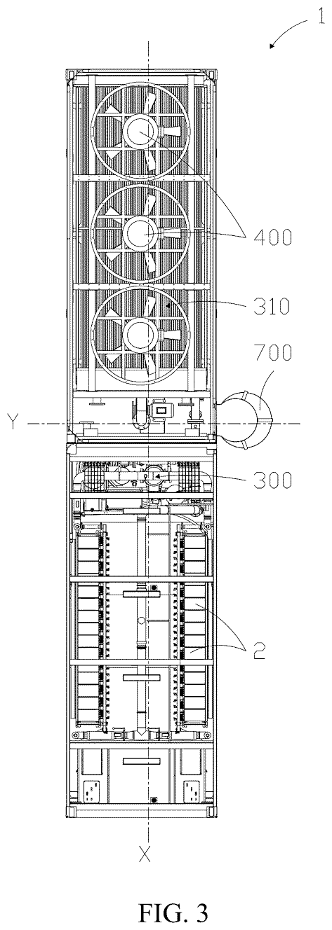

A cooling integrated system 1 is provided, please refer to FIG. 1 to FIG. 3, where FIG. 1 shows a perspective schematic diagram of a cooling integrated system according to an embodiment of the present application; FIG. 2 shows a schematic cross-sectional view of the cooling integrated system in FIG. 1 along the line A-A; and FIG. 3 shows a schematic view of the cooling integrated system from an angle according to an embodiment of the present application. The cooling integrated system 1 includes a housing 100, a rack 200 and a cooling apparatus 300 integrally packaged inside the housing 100. The rack 200 includes multiple layers of stacked placement space 201. The placement space 201 is configured to accommodate a server 2 provided with a cooling channel. The cooling apparatus 300 includes a heat exchange mechanism 310, a liquid inlet pipe 320, a liquid return pipe 330, and a delivery pump 340. The heat exchange mechanism 310 and the cooling channel are communicated by the liquid inlet pipe 320, and the heat exchange mechanism 310 and the cooling channel are communicated by the liquid return pipe 330. The delivery pump 340 is installed on the liquid inlet pipe 320 and/or the liquid return pipe 330, and the delivery pump 340 is configured to circulate coolant between the heat exchange mechanism 310 and the cooling channel to cool the server 2. In an embodiment of the present application, the server 2 is taken as an example to illustrate the present application. However, it should be understood that in other embodiments of the present application, the server 2 can also be other computing devices provided with the cooling channel.

For the above-mentioned server 2, please specifically refer to FIG. 2 and FIG. 3, the server 2 is a liquid-cooling server, and the liquid-cooling mechanism is provided with a cooling channel (not shown in the figures), and the cooling channel has a liquid inlet (not shown in the figures) and a liquid outlet (not shown in the figures). The liquid inlet is configured to connect with the liquid inlet pipe 320, and the liquid outlet is configured to connect with the liquid return pipe 330.

For the above-mentioned housing 100, please specifically refer to FIG. 1, where the housing 100 includes a first container 110 and a second container 120 connected to each other along a length direction X. The first container 110 and the second container 120 are fixed by screwing. The first container 110 is provided with a first cavity 111, and the second container 120 is provided with a second cavity 121. The rack 200, the liquid inlet pipe 320, the liquid return pipe 330, and the delivery pump 340 are provided in the first cavity 111, and the heat exchange mechanism 310 is provided in the second cavity 121. It should be noted that in an embodiment of the present application, the housing 100 is provided with the first cavity 111 and the second cavity 121 which are independent relative to each other, so as to isolate the heat exchange mechanism 310 and the server 2 relative to each other, thereby improving the cooling effect of the heat exchange mechanism 310 and preventing the heat exchange mechanism 310 from affecting the server 2 during operation. In other embodiments of the present application, the delivery pump 340 can also be provided in the second cavity 121; in addition, in some embodiments of the present application, the housing 100 is provided with only one cavity, and the server 2, the rack 200, and the cooling apparatus 300 are all provided in the same cavity. It should also be noted that in other embodiments of the present application, the first container 110 and the second container 120 can also be fixed by welding or riveting, etc., only in order to achieve the fixation between the first container 110 and the second container 120.

In an embodiment, the first container 110 and the second container 120 are both 40-foot high cube (40HQ) containers, that is, a length of the first container 110 and the second container 120 is 12.192 meters, a width thereof is 2.438 meters, and a height thereof is 2.89 meters. The rack 200, the delivery pump 340, and the heat exchange mechanism 310 are arranged in sequence along the length direction X of the container. It should be noted that the present application does not limit the specific dimensions of the first container 110 and the second container 120. In other embodiments of the present application, the first container 110 and the second container 120 can also be containers of other specifications such as a 20-foot general-purpose (20GP) container or a 45-foot high cube (45HC) container, etc., and in the present application, a container is directly configured to transform into the first container 110 and the second container 120, which can facilitate production and processing, thereby reducing production cost. However, it should be understood that in some embodiments of the present application, the first container 110 and the second container 120 can also be produced without being modified through container transformation. The first container 110 and the second container 120 can be directly manufactured through independent production and processing.

In an embodiment, a buffer pad (not shown in the figures) is provided between the first container 110 and the second container 120. The buffer pad is configured to provide buffer between the first container 110 and the second container 120, which reduces the shake of the first container 110 and second container 120 fixed by screwing during transportation, thereby mitigating wear between the first container 110 and the second container 120.

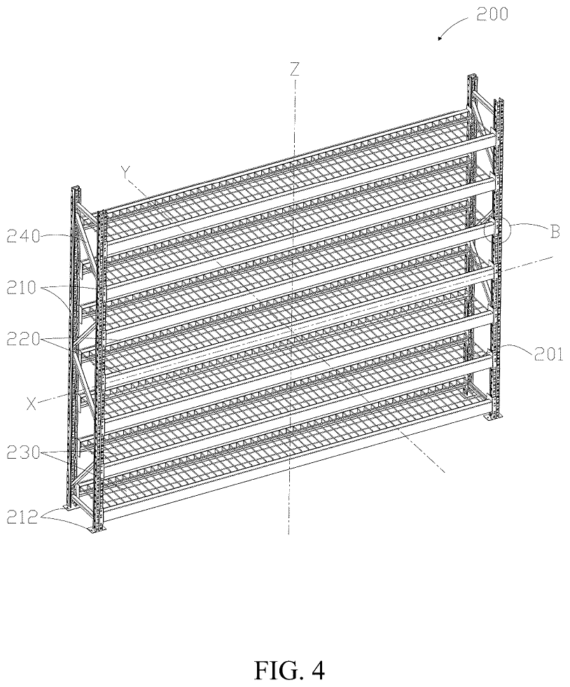

For the above-mentioned rack 200, please specifically refer to FIG. 4, FIG. 4 shows a perspective schematic diagram of a rack according to an embodiment of the present application, in combination with FIG. 1 to FIG. 3, the rack 200 includes multiple layers of stacked placement space 201. The placement space 201 is configured to accommodate the server 2. The rack 200 includes upright columns 210, carrying beams 220, and partitions 230. The number of upright columns 210 is four, and four upright columns 210 are arranged along a height direction Z. The number of carrying beams 220 is multiple, and multiple carrying beams 220 are provided along a horizontal direction, and the two ends of the carrying beams 220 are fixed between two upright columns 210. The partitions 230 are provided between two carrying beams 220 on the same horizontal plane. Two adjacent partitions 230 are spaced apart and are enclosed to form the placement space 201. The arrangement of the rack 200 allows the servers 2 to be stacked in the height direction Z, thereby increasing the capacity of the housing 100 for accommodating the servers 2.

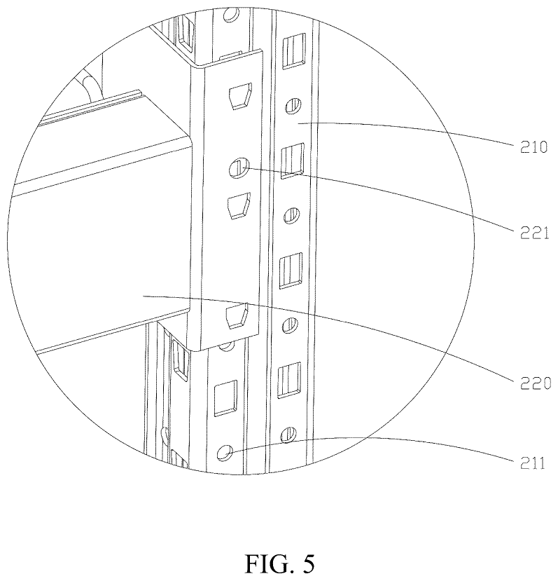

In an embodiment, please refer to FIG. 5, FIG. 5 shows a partially enlarged schematic view at B in FIG. 4. The upright column 210 is provided with a plurality of first mounting holes 211 along the height direction Z, and the carrying beam 220 is provided with a second mounting hole 221. The rack 200 also includes bolts (not shown in the figure) and nuts (not shown in the figure). The bolts are inserted into the first mounting holes 211 and the second mounting holes 221 and then screwed with the nuts, so that the carrying beam 220 is fixed to the upright column 210. By adjusting the first mounting holes 211 to match different second mounting holes 221, the height of the placement space 201 can be adjusted, so that the placement space 201 can be adapted to servers 2 of different sizes.

In an embodiment, a bottom of the upright column 210 is also provided with a fixing part 212, which is screwed and fixed to the first container 110, so that the rack 200 is fixedly installed in the first container 110, thereby preventing the rack 200 from shaking and shifting during transportation. Besides, the rack 200 is more stable when placing the server 2, thereby preventing the rack 200 from accidentally falling over, making it easier for users to install and place the server 2, and improving the user experience. It should be noted that in an embodiment of the present application, the fixing part 212 is screwed and fixed to the first container 110 to facilitate the maintenance and disassembly of the rack 200, but the present application does not limit the specific fixing mode of the fixing part 212 on the first container 110. In other embodiments of the present application, the fixing part 212 can also be fixed to the first container 110 by welding or riveting, only in order to achieve fixed installation of the rack 200 on the first container 110.

In an embodiment, the number of racks 200 is two, and the two racks 200 are arranged symmetrically along the width direction Y. The arrangement of the two racks 200 can further increase the capacity of the housing 100 for accommodating the server 2 and facilitate the installation and disassembly of the inlet pipe 320 and the liquid return pipe 330 with the cooling channel of the server 2.

In an embodiment, the partition 230 is a grille plate. The arrangement of the grille plate can reduce contact area between the partition 230 and the server 2, thereby facilitating the heat dissipation of the server 2.

In an embodiment, the rack 200 also includes a fixing plate 240. The fixing plate 240 is inclined and disposed between two opposite upright columns 210 along the width direction Y. The fixing plate 240 is configured to reinforce the strength of the rack 200 and increase carrying capacity of the rack 200.

Regarding the above-mentioned liquid inlet pipe 320, liquid return pipe 330 and delivery pump 340, both the liquid inlet pipe 320 and the liquid return pipe 330 are water pipes. The liquid inlet pipe 320 is connected to the liquid inlet, and the liquid return pipe 330 is connected to the liquid outlet. The delivery pump 340 is provided on the liquid inlet pipe 320. The liquid inlet pipe 320 and the liquid return pipe 330 are configured to communicate with the heat exchange mechanism 310 and the cooling channel, so that a sealed passage is formed between the heat exchange mechanism 310 and the cooling channel for the circulation of the coolant. It should be noted that the present application does not limit the specific location of the delivery pump 340. In other embodiments of the present application, the delivery pump 340 can also be provided at the liquid return pipe 330, or in some embodiments of the present application, the cooling apparatus 300 includes two or more delivery pumps 340. At least one delivery pump 340 is provided on the liquid inlet pipe 320, and at least one delivery pump 340 is provided on the liquid return pipe 330. Of course, multiple delivery pumps 340 can also be simultaneously and separately provided at either the liquid inlet pipe 320 or the liquid return pipe 330.

Regarding the above-mentioned heat exchange mechanism 310, the heat exchange mechanism 310 includes a plurality of heat dissipation pipes 311. The heat dissipation pipes 311 are water pipes, and a diameter of the heat dissipation pipe 311 is smaller than that of the liquid inlet pipe 320 and the liquid return pipe 330. The heat dissipation pipes 311 are contained in the second cavity 121. The heat dissipation pipes 311 extend along the length direction X. Multiple heat dissipation pipes 311 are arranged in parallel and are sequentially connected end to end. The heat dissipation pipes 311 are communicated with the liquid return pipe 330. The heat dissipation pipes 311 are configured to dissipate the coolant. The relatively smaller diameter of the heat dissipation pipe 311 and the arrangement of multiple heat dissipation pipes 311 are beneficial to enhancing the heat dissipation effect of the heat dissipation pipes 311.

In an embodiment, the second container 120 is provided with an air inlet 122 and an air outlet 123. The air outlet 123 is opened on the top of the second container 120. The air inlet 122 is opened on both sides of the second container 120 in the width direction Y. The heat dissipation pipes 311 are set close to the air outlet 123. The cooling integrated system 1 also includes a fan 400, and the number of fan 400 is three. The fans 400 are installed on the housing 100 and are configured to directly face the air outlet 123. The three fans 400 are spaced apart along the length direction X. It should be noted that the present application does not limit the specific number of the fan 400. In other embodiments of the present application, the number of the fan 400 can also be 1, 5, etc. It should also be noted that in an embodiment of the present application, the fans 400 and the heat dissipation pipes 311 are arranged close to the air outlet 123 to shorten the movement distance of hot air in the second cavity, thereby improving the cooling effect. However, in other embodiments of the present application, the fans 400 can also be arranged to directly face the air inlet 122, or in some embodiments of the present application, the fans 400 can be arranged to directly face the air outlet 123 and the air inlet 122 simultaneously. It should also be noted that in the present application, the fans 400 are configured to enhance the air flow to dissipate the heat of the coolant, but the present application does not limit the specific cooling approach of the coolant. In other embodiments of the application, the heat exchange mechanism 310 can also cool the coolant through other approaches, such as through water cooling or using a Peltier, only in order to achieve the cooling of the coolant.

In an embodiment, the cooling integrated system 1 also includes a protective fence 500. The protective fence 500 is installed on the second container 120 and is arranged around the fan 400. The arrangement of the protective fence 500 can protect the fan 400 while ensuring the ventilation effect, and can reduce the probability of external objects impacting the fan 400, thereby increasing the service life of the fan 400.

In an embodiment, the fan 400 and the protective fence 500 are detachably installed on the second container 120. During transportation, the fan 400 and the protective fence 500 located outside the second container 120 can be removed, so that the cooling integrated system 1 to be transported directly in form of a container, which prevents the fan 400 and the protective fence 500 from being damaged due to collisions during transportation, making transportation more convenient.

In an embodiment, the cooling integrated system 1 also includes a ladder 600. The ladder 600 is processed and formed from an outside of the second container 120. The ladder 600 is used for users to climb onto the second container 120, thereby facilitating the disassembly and installation of the fan 400 and the protective fence 500. Moreover, the ladder 600 is directly processed and formed from the second container 120. On the other hand, the ladder 600 does not protrude from the outside of the second container 120, which prevents the ladder 600 from being damaged due to collisions during transportation, making transportation more convenient.

In an embodiment, the cooling integrated system 1 also includes a ladder protection cage 700. The ladder protection cage 700 is detachably installed on the second container 120 and is provided relative to an upper portion of the ladder 600. The ladder protection cage 700 provides protection for the users installing the fan 400 and the protective fence 500. Before using the cooling integrated system 1, the users can first install the ladder protection cage 700, and then install the fan 400 and protective fence 500.

In an embodiment, the cooling integrated system 1 also includes a power distribution cabinet 800 and a control apparatus 900. In the length direction X, the power distribution cabinet 800 is provided on a side of the rack 200 facing away from the heat exchange mechanism 310 and close to a cabinet door. The control apparatus 900 is provided above the power distribution cabinet 800. The power distribution cabinet 800 is configured to supply power to the server 2, and the control apparatus 900 is configured to control the cooling apparatus 300 and the power distribution cabinet 800. The power distribution cabinet 800 and the control apparatus 900 are arranged close to the cabinet door to facilitate control operations. The number of both the power distribution cabinets 800 and the control apparatuses 900 is two. The power distribution cabinets 800 and the control apparatuses 900 are arranged in one-to-one correspondence and are arranged symmetrically in the width direction Y.

The flow directions of the coolant in the cooling integrated system 1 will be briefly described below with reference to the accompanying drawings, wherein:
1. the coolant absorbs heat of a computing board in the cooling channel, causing its temperature to rise;
2. the coolant flows from the liquid outlet through the liquid return pipe 330 to the heat exchange mechanism 310;
3. the coolant dissipates heat in the heat dissipation pipe 311, and flows into the liquid inlet pipe 320 after the temperature drops;
4. the coolant flows from the liquid inlet pipe 320 through the liquid inlet into the cooling channel.

The cooling apparatus 300 of the cooling integrated system 1 of the present application is integrally configured. When in use, the users do not need to connect the internal pipes of the cooling apparatus 300 personally. Moreover, after removing the fan 400, protective fence 500, and ladder protection cage 700, the cooling integrated system 1 can be transported directly as a container, making transportation convenient and cost low.

The present application also provides another embodiment of the cooling integrated system 1. In this embodiment, the housing 100 includes one container, the interior of which is divided along the length direction X to form a first cavity 111 and a second cavity 121. The rack 200, the liquid inlet pipe 320, the liquid return pipe 330, and the delivery pump 340 are provided in the first cavity 111, and the heat exchange mechanism 310 is provided in the second cavity 121.

The above are only specific embodiments of the present application, but the protection scope of the present application is not limited thereto. Any person skilled in the art can easily conceive of various equivalent modifications or replacements within the technical scope disclosed in the present application, and these modifications or replacements shall be covered by the protection scope of the present application. Therefore, the protection scope of the present application should be subject to the protection scope of the claims.

What is claimed is:

1. A cooling integrated system, for cooling a computing device provided with a cooling channel, comprising a housing and a cooling apparatus integrally packaged inside the housing; wherein the cooling apparatus comprises a heat exchange mechanism, a liquid inlet pipe, a liquid return pipe, and a delivery pump, the heat exchange mechanism and the cooling channel are communicated by the liquid inlet pipe, the heat exchange mechanism and the cooling channel are communicated by the liquid return pipe, and the delivery pump is installed on the liquid inlet pipe and/or the liquid return pipe and configured to circulate coolant between the heat exchange mechanism and the cooling channel to cool the computing device.

2. The cooling integrated system according to claim 1, wherein the housing comprises a container, and the cooling apparatus is accommodated inside the container.

3. The cooling integrated system according to claim 2, wherein an interior of the container is divided along a length direction to form a first cavity and a second cavity, the liquid inlet pipe and the liquid return pipe are provided in the first cavity, the heat exchange mechanism is provided in the second cavity, and the delivery pump is provided in the first cavity and/or the second cavity.

4. The cooling integrated system according to claim 3, wherein the cooling integrated system further comprises a rack, and the rack is accommodated in the first cavity, the rack comprises multiple layers of stacked placement space, and the placement space is configured to accommodate the computing device provided with the cooling channel.

5. The cooling integrated system according to claim 4, wherein the cooling integrated system further comprises a power distribution cabinet, and the power distribution cabinet is provided on a side of the rack facing away from the heat exchange mechanism in the length direction.

6. The cooling integrated system according to claim 5, wherein the cooling integrated system further comprises a control apparatus, and the control apparatus is provided above the power distribution cabinet.

7. The cooling integrated system according to claim 3, wherein the container is provided with an air inlet and an air outlet;
the cooling integrated system further comprises a fan, and the fan is installed on the container and arranged to directly face the air outlet and/or the air inlet.

8. The cooling integrated system according to claim 7, wherein the number of the fan is three, and the three fans are arranged in a row along the length direction.

9. The cooling integrated system according to claim 7, wherein the cooling integrated system further comprises a protective fence, and the protective fence is installed on the container and arranged around the fan.

10. The cooling integrated system according to claim 9, wherein the fan and the protective fence are detachably installed on the container.
